(19) United States
(12) Patent Application Publication
(10) Pub. No.: US 2011/0147851 A1
(43) Pub. Date: Jun. 23, 2011

(54) Method For Depositing Gate Metal For CMOS Devices

(76) Inventors: Christopher D. Thomas, Aloha, OR (US); Joseph M. Steigerwald, Forest Grove, OR (US); Timothy E. Glassman, Portland, OR (US); Kyoung H. Kim, Portland, OR (US); Dan S. Lavric, Beaverton, OR (US); Michael Ollinger, Portland, OR (US); M. N. Perez-Paz, Hillsboro, OR (US)

(21) Appl. No.: 12/641,497

(22) Filed: Dec. 18, 2009

(51) Int. Cl. H01L 27/092; H01L 21/8238

(52) U.S. Cl. 257/369; 438/589; 257/E21.635; 257/E27.062

(57) ABSTRACT

A semiconductor device comprises a substrate, a channel region, and a gate formed in association with the channel region. In one exemplary embodiment, the gate comprises a first material that is formed void free on an interior surface of a gate trench of the gate. A width of the gate trench comprises between about 8 nm and about 65 nm. The gate comprises a transition metal alloyed with carbon, aluminum or nitrogen, or combinations thereof, to form a carbide, a nitride, or a carbo-nitride, or combinations thereof, of the transition metal. In another exemplary embodiment, the gate further comprises a second material formed void free on an interior surface of the first material and comprises a transition metal alloyed with carbon, aluminum or nitrogen, or combinations thereof, to form a carbide, a nitride, or a carbo-nitride, or combinations thereof, of the transition metal.

### BACKGROUND

In a replacement gate CMOS process, or flow, the material(s) forming the gate of a transistor is deposited into a gate trench having dimensions that are about the gate width of the transistor.

### BRIEF DESCRIPTION OF THE DRAWINGS

Embodiments disclosed herein are illustrated by way of example, and not by way of limitation, in the figures of the accompanying drawings in which like reference numerals refer to similar elements and in which:

FIGS. 1A and 1B respectively depict simplified schematics of exemplary gate stack structures for a planar-geometry CMOS device and a finFET-geometry CMOS device;

FIGS. 1C and 1D respectively depict in greater detail exemplary gate stack structures formed by a replacement gate flow and by a subtractive gate flow;

FIG. 2 shows a flow diagram for a replacement gate flow for forming a gate stack for both a planar- and a finFET-geometry CMOS device using an atomic layer deposition (ALD) technique according to the subject matter disclosed herein; and

FIG. 3 is a diagram of an exemplary embodiment of a system in which a CMOS device formed according to the subject matter disclosed herein may be used.

It will be appreciated that for simplicity and/or clarity of illustration, elements illustrated in the figures have not necessarily been drawn to scale. For example, the dimensions of some of the elements may be exaggerated relative to other elements for clarity. Further, if considered appropriate, reference numerals have been repeated among the figures to indicate corresponding and/or analogous elements.

### DETAILED DESCRIPTION

Embodiments are described herein of methods for depositing materials, such as transition metal carbides and transition metal carbo-nitrides, for gates of CMOS devices. In the following description, numerous specific details are set forth to provide a thorough understanding of embodiments disclosed herein. One skilled in the relevant art will recognize, however, that the embodiments disclosed herein can be practiced without one or more of the specific details, or with other methods, components, materials, and so forth. In other instances, well-known structures, materials, or operations are not shown or described in detail to avoid obscuring aspects of the specification.

Reference throughout this specification to “one embodiment” or “an embodiment” means that a particular feature, structure or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments. The word “exemplary” is used herein to mean “serving as an example, instance, or illustration.” Any embodiment described herein as “exemplary” is not to be construed as necessarily preferred or advantageous over other embodiments.

The material(s) forming the gate of a metal-gate CMOS transistor, or device, for both a device having a planar-geometry or a finFET-geometry, does two things in some embodiments: the material(s) provides a suitable work function (which sets the device's threshold voltage) and has relatively low resistivity to reduce losses when this device is used in a circuit. Both functions could be provided by one material. Alternatively, a stack of two different materials (or a multi-layered stack) can be used that separately provide each respective function and have been optimized for each function to meet the particular needs of the technology of the CMOS device. Sometimes when two materials are used, a third material may promote adhesion between the first two materials or to serve as a diffusion barrier between the two materials.

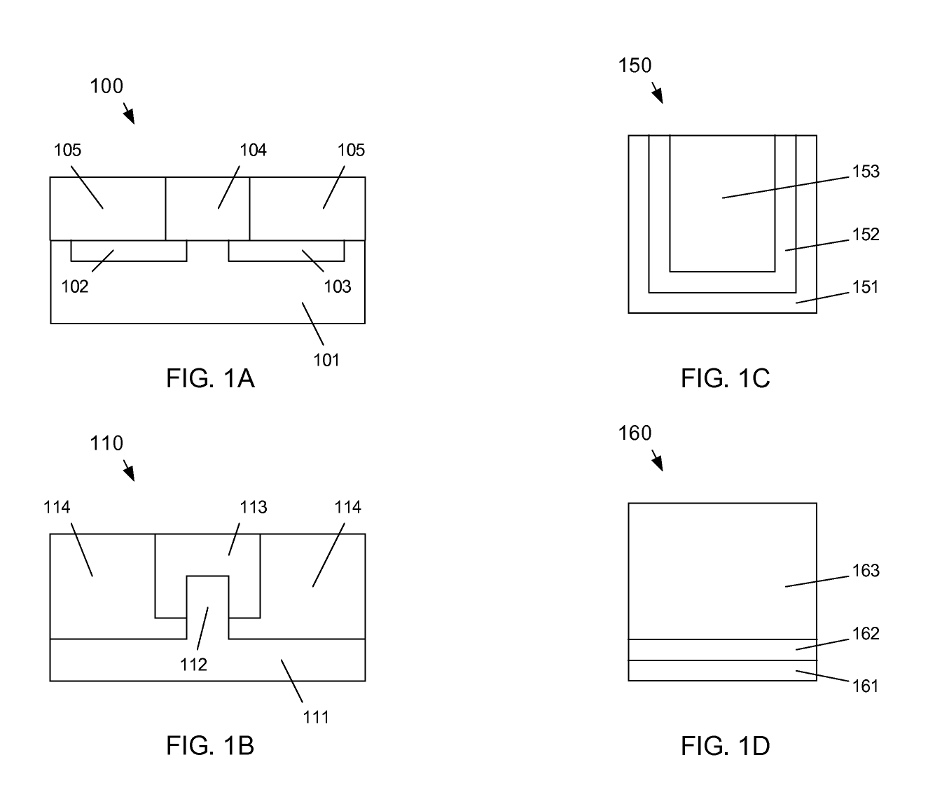

FIGS. 1A and 1B respectively depict simplified schematics of exemplary gate stack structures for a planar-geometry CMOS device 100 and a finFET-geometry CMOS device 110. In FIG. 1A, planar-geometry CMOS device 100 comprises a substrate 101, a source region 102, a drain region 103, a gate structure 104, and other well-known structures 105, such as isolation regions and/or source and drain contacts. Source region 102 and drain region 103 are formed in substrate 101 in a well-known manner. Other well-known structures that are associated with planar-geometry CMOS device 100, such as, but not limited to, a gate dielectric layer, are not shown in FIG. 1A. Gate structure 104 is formed on substrate 101 using either a replacement gate flow or a subtractive gate flow.

In FIG. 1B, finFET-geometry CMOS device 110 comprises a substrate 111, a fin structure 112, a gate structure 113 and other well-known structures 114, such as isolation regions and/or source and drain contacts. In one exemplary embodiment, a source region (not indicated) would be located along fin structure 112 in front of fin structure 112 as viewed in FIG. 1B, while a drain region (not indicated) would be located along fin structure 112 behind fin structure 112 as viewed in FIG. 1B. In another exemplary embodiment, a drain region (not indicated) would be located along fin structure 112 in front of fin structure 112 as viewed in FIG. 1B, while a source region (not indicated) would be located along fin structure 112 behind fin structure 112 as viewed in FIG. 1B. Other well-known structures that form finFET-geometry CMOS device 110, such as, but not limited to a gate dielectric layer, are not shown in FIG. 1B for clarity. Gate structure 113 is formed around fin structure 112 using either a replacement gate flow or a subtractive gate flow.

FIGS. 1C and 1D respectively depict in greater detail exemplary gate stack structures formed by a replacement gate flow and by a subtractive gate flow. More specifically, FIG. 1C depicts an exemplary gate stack structure 150 that has been formed by a replacement gate flow, and FIG. 1D depicts an exemplary gate stack structure 160 that has been formed by a subtractive gate flow. In FIG. 1C, exemplary gate stack structure 150 comprises a work function metal 151, an adhesion or barrier layer 152, and a fill material 153. In an alternative exemplary embodiment, gate stack structure 150 might not include adhesion or barrier layer 152. In FIG. 1D, exemplary gate stack structure 160 comprises a work function metal 161, an adhesion or barrier layer 162, and a fill material 163. In an alternative exemplary embodiment, gate stack structure 160 might not include adhesion or barrier layer 162.

According to some embodiments of the subject matter disclosed herein, the materials that can be used in a replacement or a subtractive gate flow to form a gate stack for either a planar-geometry or a finFET-geometry CMOS device comprise a transition metal alloyed with carbon, aluminum or nitrogen, or combinations thereof, to form a carbide, a nitride or a carbo-nitride of the metal. The carbide, nitride or carbo-nitride of the metal is deposited into a gate trench to form conformal films by using either an atomic layer deposition (ALD) technique or a chemical vapor deposition (CVD) technique.

It should be understood that the subject matter disclosed herein is also applicable to a finFET-type of device in which the gate is formed on the top and sidewalls of the fin (commonly referred to as a Tri-gate transistor). For convenience herein, the materials that can be used in a replacement gate flow to form a gate stack for a CMOS device are referred to as M-C, M-N, or M-C—N, in which M stands for a metal and mixtures of metals, such as aluminum, barium, chromium, cobalt, hafnium, iridium, iron, lanthanum and other lanthanides, molybdenum, niobium, osmium, palladium, platinum, rhenium, ruthenium, rhodium, scandium, strontium, tantalum, titanium, tungsten, vanadium, yttrium, zinc, or zirconium, and in which C and N respectively stand for carbon and nitrogen.

The films formed by some embodiments of the techniques disclosed herein are void-free and conformal, and unlike conventional PVD techniques for forming gate metal films in gate trenches, both the ALD and CVD techniques disclosed herein can provide precise control of the film thickness. Moreover, the flow process can be controlled to set a selected transistor threshold voltage that is appropriate for both NMOS- and PMOS-type devices, and the films can be used in a multilayered gate with a portion of the gate designed to set the work function, and a portion of the gate optimized for low resistance. While conventional PVD techniques have resulted in voiding when attempting to form these gate materials having gate widths in the range of between about 8 nm and about 65 nm, the techniques disclosed herein can result in substantially void-free films. Accordingly, in one exemplary embodiment, the techniques disclosed herein can be used to form substantially void-free conformal films for gate widths in the range of between about 8 nm and about 32 nm. In yet another exemplary embodiment, the techniques disclosed herein can be used to form substantially void-free conformal films for gate widths in the range of between about 8 nm and about 16 nm.

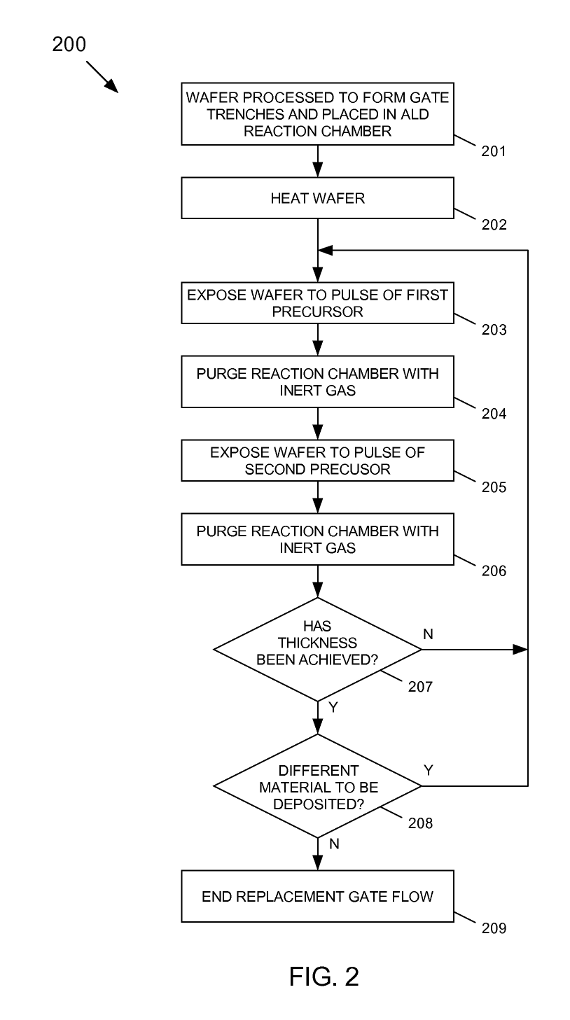

FIG. 2 shows a flow diagram for a replacement gate flow 200 for forming a gate stack for both a planar- and a finFET-geometry CMOS device using an atomic layer deposition (ALD) technique according to the subject matter disclosed herein. Replacement gate flow 200 is carried out in a reaction chamber of an ALD reactor. Additionally, in one exemplary embodiment, flow 200 could be performed in a batch manner in which multiple wafers are simultaneously processed. In another exemplary embodiment, flow 200 could be performed on individual wafers. Moreover, because, strictly speaking, an ALD process is an adsorption-limited process and film growth is completely controlled by the number of cycles, the overall deposition process could be adjusted to be a chemical vapor deposition (CVD) process in which film growth is determined by the amount of material entering into the reaction chamber. Consequently, the following process is described in terms of an exemplary ALD process, but could be adjusted to be an exemplary CVD process and achieve similar results.

At step 201, a wafer that has already been processed in a well-known manner to form gate trenches is placed into a heated ALD chamber on a heated susceptor. A carrier gas is connected to multiple chemical precursor vessels (i.e., precursor 1, precursor 2, etc.). The carrier gas could be nitrogen, argon, or some other inert gas, or combinations thereof. The vessels may be heated or cooled in a well-known manner to produce appropriate vapor pressures.

The carrier gas is controlled in a well-known manner using, for example, mass-flow controllers and valves so that the carrier gas can be directed to the chamber through the precursor vessels or so the carrier gas can be sent directly into the reaction chamber of the ALD reactor with no reactive vapors. The mass-flow controller enables controllable selection of various flow rates. The geometry of admitting gas into the reaction chamber can be in a cross flow configuration (that is, introduced on one side of the chamber and exhausted in the opposite end), in a showerhead configuration (that is, from above the wafer and exhausted below the wafer), or in more exotic configurations (for example, a separate inlet for each reactive gas), or combinations thereof. As used herein, the terms “pulse” or “pulse of a carrier gas” refer to when a carrier gas is released into a precursor vessel. As also used herein, the terms “purge” or “purge of a carrier gas” refers to when a carrier gas is released directed into an ALD reaction chamber without other vapors. It should be understood alternative techniques ALD techniques, such as “direct liquid injection” or where the precursor is supplied in a gas phase, could be used with the subject matter disclosed herein.

At step 202, the wafer is heated to a temperature of between about 15° C. and about 650 C. During deposition, the pressure of the reaction chamber is set to be between about 0.25 Torr and about 15 Torr. It should be understood that the pressure may be selectably changed during the ALD process.

At step 203, the wafer is exposed to a pulse of a transition-metal precursor. Suitable transition-metal precursors include, but are not limited to, transition-metal halides, transition-metal alkylamides, or other organometallic compounds, or combinations thereof. Suitable transition-metal halides include MClx, MIx, MBrx, and MFx. Suitable transition-metal alkylamides include, for example dimethylamino-metal compounds (written M[NMe2]x where NMe2 is a nitro-dimethyl group), and diethylamino-metal compounds (written M[NEt2]x), ethylmethylamino-metal compounds (written M[NEtMe]x), and tertbutylimidotris˜diethylamido compounds. Precursors may also be based on other organometallic compounds including diketonato complexes, cyclopentadyenyls, alkoxides, and carbonyls.

The length of the pulse is between about 0.05 seconds and about 25 seconds. Typically, a carrier gas is admitted into the precursor vessel at between about 0.1 to about 10.0 standard liters per minute (SLM). A derivative of the transition-metal precursor is adsorbed into the wafer surface during this pulse and, in particular, the surfaces of a gate trench of a CMOS device.

At step 204, the reaction chamber is purged with an inert gas for about between 0 seconds and about 60 seconds at between about 0.1 SLM and about 10.0 SLM. Instead of purging, the reaction chamber could alternatively only be evacuated for between about 0 seconds and about 600 seconds. For yet another exemplary alternative embodiment, both purging and evacuation could be performed.

At step 205, the wafer is then exposed to a pulse of a second precursor that reacts with the material that has been adsorbed on the surface of the wafer to form a carbide or an alloy carbide. Suitable materials for the second precursor include, but are not limited to, aluminum alkyls, aluminum hydrides; aluminum halides, aluminum oxides, or other adducts. So, for example, this second precursor could be Suitable aluminum alkyls include, but are not limited to, tri-methyl aluminum (TMA), tri-ethyl aluminuin (TEA), and tris(diethyl amino) aluminum. Suitable aluminum hydrides include, but are not limited to, diisobutyl aluminum hydride (DIBAH), dimethylaluminum hydride (TEMAH), or aluminum hydride (or alane). Suitable aluminum halides include, but are not limited to, aluminum tri-chloride and aluminum tri-bromide. Suitable aluminum oxides include, but are not limited to, diethylaluminum ethoxide, aluminum isopropoxide, and aluminum 2-ethyhexanoate. It should be understood that other metal precursors may be substituted for the aluminum-based second precursor, for example, tri-methyl borane can be substituted for tri-methyl aluminum. The carrier gas is admitted into the precursor vessel at between about 0.1 SLM and about 10.0 SLM. In an alternative exemplary embodiment, if the precursor is liquid, the second precursor may be directly injected into the reaction chamber or into an injection chamber positioned immediately upstream of the reaction chamber.

At step 206, the reaction chamber is purged with an inert gas for about between 0 seconds and about 60 seconds at between about 0.1 SLM and about 10.0 SLM. Instead of purging, the reaction chamber could alternatively only be evacuated for between 0 seconds and about 600 seconds. As yet another exemplary alternative embodiment, both purging and evacuation could be performed.

At step 207, it is determined whether the desired thickness of the material being deposited by ALD deposition has been achieved. If, at step 207, the desired thickness has not been achieved, flow returns to step 203 where the cycle of steps 203 through 207 is repeated. The sequence from step 203 to step 207 are commonly referred to as a “cycle.”

If, at step 207, the desired thickness has been achieved, flow continues to step 208. At step 208, a decision is made regarding whether the desired configuration of the gate stack has been achieved and whether another material is to be deposited. For example, the material being deposited by could be formed as a complete gate stack without multilayering. Alternatively, the gate stack could be formed to be a multi-layer stack. For example, in one exemplary gate stack configuration that could be formed using the subject matter disclosed herein, one material is deposited using an ALD (or a CVD) technique to form the entire gate stack. In another exemplary gate stack, the gate stack comprises two different materials that have each been optimized to respectively provide the function of setting the threshold voltage of the device and the function of providing low resistivity for conducting current into the gate of the device. Moreover, a third material may sometimes be used to promote adhesion between the first two materials or to serve as a diffusion barrier between the two materials.

Tables 1 and 2 respectively set forth different exemplary configurations of gate stacks for NMOS and PMOS devices that can be formed using the subject matter disclosed herein.

TABLE 1
Exemplary NMOS Gate Stack Configurations

| Exemplary | Work | | |
|---|---|---|---|
| NMOS | Function | | |
| Configuration | Metal | Adhesion or Barrier | Fill Metal |
| 1 | M-C | As needed to deposit | Low-resistance |
| | | and contain fill metal | metal |
| 2 | M-C | M-C-N or M-N | Low-resistance |
| | | | metal |
| 3 | Some other | As needed to deposit | M-C |
| | NMOS | and contain fill metal | |
| | metal | | |
| 4 | M-C | None | M-C |

TABLE 2
Exemplary PMOS Gate Stack Configurations

| Exemplary | Work | | |
|---|---|---|---|
| PMOS | Function | | |
| Configuration | Metal | Adhesion or Barrier | Fill Metal |
| 1 | M-C-N or | None | Low-resistance |
| | M-N | | metal |
| 2 | Some other | As needed to deposit | M-C |
| | PMOS | over PMOS metal | |
| | metal M-C | | |
| 3 | M-C-N or | None | M-C |
| | M-N | | |

Depending on the desired gate stack configuration, a different number of materials may be deposited during flow 200. For example, for the fourth exemplary gate stack configuration for an NMOS device, both the work-function metal and the fill is M-C.

For the second exemplary gate stack configuration for an NMOS device, the work-function metal is M-C; the “third” material is M-C—N or M-N is used for an adhesion or a barrier layer; and the fill material is a low-resistance metal. One specific exemplary embodiment of the second exemplary gate stack configuration for an NMOS device comprises an ALD-deposited (or CVD-deposited) M-C comprising between about 0% and about 80% M; between about 0% and about 60% aluminum; and between about 0% and about 60% carbon, in which M is a metal including, but not limited, to Al, Ba, Hf, La, Mg, Nb, Sc, Sr, Ta, Ti, V, Y, or Zr, or mixtures thereof.

For the third exemplary gate stack configuration for a PMOS device, the work function metal is M-C—N or M-N, there is no “third” material that is used for a barrier or an adhesion layer, and the fill material is M-C. One specific exemplary embodiment of the third exemplary gate stack configuration for a PMOS device comprises an ALD-deposited (or CVD-deposited) M-C—N comprising between about 0% and about 100% M; between about 0% and about 60% aluminum; between about 0% and about 60% carbon and between about 0% and about 60% nitrogen in which M is a transition metal including, but not limited to, Al, Co, Cr, Hf, Mo, Ni, Nb, Pd, Pt, Re, Rh, Ru, Ta, Ti, Tc, V, W, or Zr or mixtures thereof.

If, at step 208, it is determined that another material is to be formed by ALD deposition, flow returns to step 203 where the cycle of steps 203 through 207 is repeated. If, at step 208, it is determined that the desired configuration of the gate stack is complete, then flow continues to step 209 where the process ends.

Flow 200 could be modified in the following ways. In one exemplary alternative embodiment, the order that the precursors are introduced in flow 200 in steps 203 and 205 could be exchanged. In another exemplary alternative embodiment, a third metallic precursor could be introduced during the cycle of steps 203-208 to form various alloys, such as, M1-M2-C or M1-M2-C—N, in which M1 and M2 are different transition metals. In still another exemplary alternative embodiment, a third precursor, such as ammonia (NH₃) or other amide precursor, could incorporated into the pulsing and purging sequence of steps 203-206 to form am M-C—N alloy that is deposited into a gate stack.

As yet another exemplary alternative embodiment, a “plasma enhanced atomic layer deposition” technique or PEALD technique could be used by exposing the wafer to a plasma to improve resistance, facilitate carbide formation, adjust the work function, or to reduce impurities, or combinations thereof. The plasma may be direct, that is, the wafer is directly in the plasma, or the plasma may be indirect, that is, the plasma is formed in a separate chamber and then directed to the wafer. The plasma may be formed using radio frequency (RF) excitations or using direct current (DC), and may be formed from, for example, methane, ethane, hydrogen, ammonia, argon, or a mixture of gasses. Exposure of the wafer to a plasma could be performed prior to or after each cycle, prior to or after a series of cycles, or prior to or after the entire deposition of the film. Further, exposure to of the wafer a plasma could be carried out in a separate chamber different from the reaction chamber described above.

In another exemplary alternative embodiment, the precursor pulse or purge times could be changed in-situ to form a non-homogenous structure. For example, one exemplary choice of a PMOS metal-gate film would be a film having more M-N bonding during the initial cycles and more M-C bonding during the final cycles.

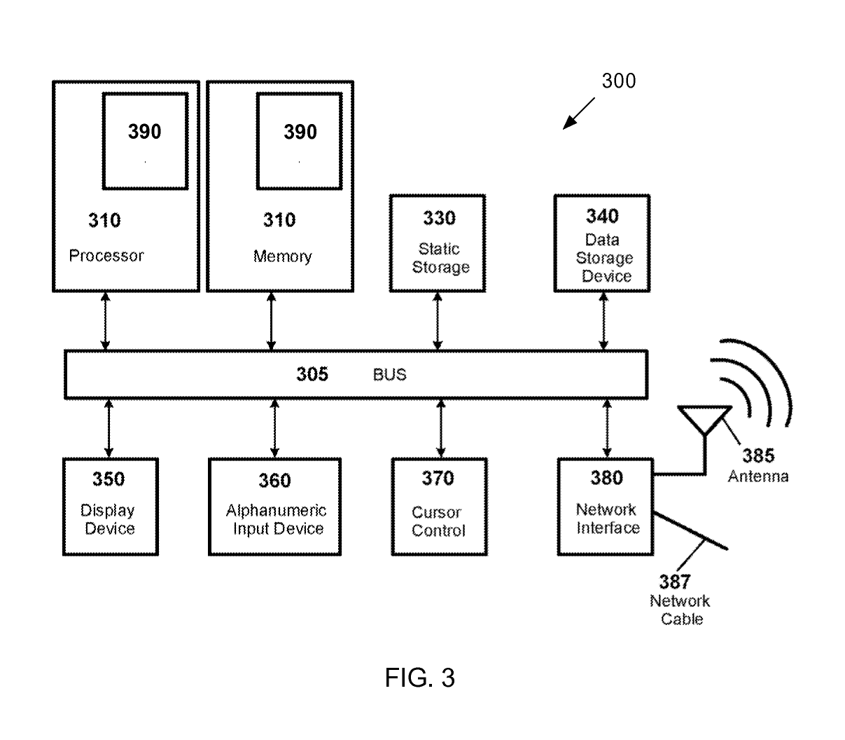

FIG. 3 is a diagram of an exemplary embodiment of a system in which a CMOS device 390 formed according to the subject matter disclosed herein may be used. System 300 is intended to represent a range of electronic systems (either wired or wireless) including, for example, desktop computer systems, laptop computer systems, personal computers (PC), wireless telephones, personal digital assistants (PDA) including cellular-enabled PDAs, set top boxes, pocket PCs, tablet PCs, DVD players, or servers, but is not limited to, these examples and may comprise other electronic systems. Alternative electronic systems may comprise more, fewer and/or different components.

In one exemplary embodiment, electronic system 300 comprises a CMOS device 390 formed according to the subject matter disclosed herein. In another exemplary embodiment, a CMOS device 390 formed according to the subject matter disclosed herein is part of an electronic system's processor 310 or memory 320. Electronic system 300 may comprise a processor 310 and memory 320 coupled with the processor 310, wherein the processor 310 or the memory 320, or combinations thereof, comprise a CMOS device 390 formed according to the subject matter disclosed herein.

Electronic system 300 may comprise bus 305 or other communication device to communicate information, and processor 310 coupled to bus 305 that may process information. While electronic system 300 may be illustrated with a single processor, system 300 may comprise multiple processors and/or co-processors. In an exemplary embodiment, processor 310 comprising a CMOS device 390 formed according to the subject matter disclosed herein. System 300 may also comprise random access memory (RAM) or other storage device 320 (may be referred to as memory), coupled to bus 305 and may store information and instructions that may be executed by processor 310.

Memory 320 may also be used to store temporary variables or other intermediate information during execution of instructions by processor 310. Memory 320 is a flash memory device in one exemplary embodiment. In another exemplary embodiment, memory 320 comprises a CMOS device 390 formed according to the subject matter disclosed herein.

System 300 may also comprise read only memory (ROM) and/or other static storage device 330 coupled to bus 305 that may store static information and instructions for processor 310. Data storage device 340 may be coupled to bus 305 to store information and instructions. Data storage device 340, such as a magnetic disk or optical disc and corresponding drive, may be coupled with electronic system 300.

Electronic system 300 may also be coupled via bus 305 to display device 350, such as a cathode ray tube (CRT) or liquid crystal display (LCD), to display information to a user. Alphanumeric input device 360, including alphanumeric and other keys, may be coupled to bus 305 to communicate information and command selections to processor 310. Another type of user input device is cursor control 370, such as a mouse, a trackball, or cursor direction keys to communicate information and command selections to processor 310 and to control cursor movement on display 350.

Electronic system 300 further may comprise one or more network interfaces 380 to provide access to network, such as a local area network. Network interface 380 may comprise, for example, a wireless network interface having antenna 385, which may represent one or more antennae. Network interface 380 may also comprise, for example, a wired network interface to communicate with remote devices via network cable 387, which may be, for example, an Ethernet cable, a coaxial cable, a fiber optic cable, a serial cable, or a parallel cable.

In one exemplary embodiment, network interface 380 may provide access to a local area network, for example, by conforming to an Institute of Electrical and Electronics Engineers (IEEE) standard such as IEEE 802.11b and/or IEEE 802.11g standards, and/or the wireless network interface may provide access to a personal area network, for example, by conforming to Bluetooth standards. Other wireless network interfaces and/or protocols could also be supported.

IEEE 802.11b corresponds to IEEE Std. 802.11b-1999 entitled “Local and Metropolitan Area Networks, Part 11: Wireless LAN Medium Access Control (MAC) and Physical Layer (PHY) Specifications: Higher-Speed Physical Layer Extension in the 2.4 GHz Band,” approved Sep. 16, 1999, as well as related documents. IEEE 802.11g corresponds to IEEE Std. 802.11g-2003 entitled “Local and Metropolitan Area Networks, Part 11: Wireless LAN Medium Access Control (MAC) and Physical Layer (PHY) Specifications, Amendment 4: Further Higher Rate Extension in the 2.4 GHz Band,” approved Jun. 27, 2003, as well as related documents. Bluetooth protocols are described in “Specification of the Bluetooth System: Core, Version 1.1,” published Feb. 22, 2001, by the Bluetooth Special Interest Group, Inc. Previous or subsequent versions of the Bluetooth standard may also be supported.

In addition to, or instead of, communication via wireless LAN standards, network interface(s) 380 may provide wireless communications using, for example, Time Division, is Multiple Access (TDMA) protocols, Global System for Mobile Communications (GSM) protocols, Code Division, Multiple Access (CDMA) protocols, and/or any other type of wireless communications protocol.

In an embodiment, a system 300 comprises one or more omnidirectional antennae 385, which may refer to an antenna that is at least partially omnidirectional and/or substantially omnidirectional, and a processor 310 coupled to communicate via the antennae.

The above description of illustrated embodiments, including what is described in the Abstract, is not intended to be exhaustive or to limit to the precise forms disclosed. While specific embodiments and examples are described herein for illustrative purposes, various equivalent modifications are possible within the scope of this description, as those skilled in the relevant art will recognize.

These modifications can be made in light of the above detailed description. The terms used in the following claims should not be construed to limit the scope to the specific embodiments disclosed in the specification and the claims. Rather, the scope of the embodiments disclosed herein is to be determined by the following claims, which are to be construed in accordance with established doctrines of claim interpretation.

What is claimed is:

1. A semiconductor device, comprising:
a substrate;
a channel region formed on or in the substrate; and
a gate formed in association with the channel region, the gate comprising a material that is formed on an interior surface of a gate trench of the gate, the material being substantially void-free.

2. The semiconductor device according to claim 1, wherein a width of the gate trench of the gate comprises between about 8 nm and about 65 nm.

3. The semiconductor device according to claim 2, wherein the material forming the gate comprises a first material formed as a substantially void-free conformal film on an interior surface of a gate trench of the gate, and
wherein the first material comprises a transition metal alloyed with carbon, aluminum or nitrogen, or combinations thereof, to form a carbide, a nitride, or a carbo-nitride, or combinations thereof, of the transition metal.

4. The semiconductor device according to claim 3, wherein the first material formed on the interior surface of the gate trench comprises a work-function metal that sets a threshold voltage of the CMOS device at a predetermined threshold.

5. The semiconductor device according to claim 4, wherein the width of the gate trench of the gate comprises between about 8 nm and about 32 nm.

6. The semiconductor device according to claim 5, wherein the CMOS device comprises a planar-geometry CMOS device or a finFET-geometry CMOS device.

7. The semiconductor device according to claim 6, wherein the first material is formed by an atomic layer deposition (ALD) technique or a chemical vapor deposition (CVD) technique, or a combination thereof.

8. The semiconductor device according to claim 3, wherein the first material comprises an interior surface that corresponds to the interior surface of the gate trench, and
wherein the gate further comprises a second material formed on an interior surface of the first material, the second material being substantially void-free and comprising a transition metal alloyed with carbon, aluminum or nitrogen, or combinations thereof, to form a carbide, a nitride, or a carbo-nitride, or combinations thereof, of the transition metal.

9. The semiconductor device according to claim 8, wherein the first material comprises a work-function metal layer, and the second material comprises a gate fill layer.

10. The semiconductor device according to claim 9, wherein the width of the gate trench of the gate comprises between about 8 nm and about 32 nm.

11. The semiconductor device according to claim 10, wherein the CMOS device comprises a planar-geometry CMOS device or a finFET-geometry CMOS device.

12. The semiconductor device according to claim 11, wherein the second material is formed by an atomic layer deposition (ALD) technique or a chemical vapor deposition (CVD) technique, or a combination thereof.

13. The semiconductor device according to claim 8, wherein the second material formed on the interior surface of the first material comprises an adhesive layer or a barrier layer, or a combination thereof, and the second material comprises an interior surface that corresponds to the interior surface of the first material and to the interior surface of the gate trench of the gate, and
wherein the gate further comprises a third material formed on the interior surface of the second material, the third material being substantially void-free and comprising a transition metal alloyed with carbon, aluminum or nitrogen, or combinations thereof, to form a carbide, a nitride, or a carbo-nitride, or combinations thereof, of the transition metal.

14. The semiconductor device according to claim 13, wherein the first material comprises a work-function metal layer, and the third material comprises a gate fill layer.

15. The semiconductor device according to claim 14, wherein the width of the gate trench of the gate comprises between about 8 nm and about 32 nm.

16. The semiconductor device according to claim 15, wherein the CMOS device comprises a planar-geometry CMOS device or a finFET-geometry CMOS device.

17. The semiconductor device according to claim 16, wherein the third material is formed by an atomic layer deposition (ALD) technique or a chemical vapor deposition (CVD) technique, or a combination thereof.

18. A method for forming a gate for a semiconductor device, the method comprising:
providing a gate trench of the semiconductor device, the gate trench comprising an interior surface of the gate trench, and a width of the gate trench of the gate comprising between about 8 nm and about 65 nm.;
forming a first gate material on the interior surface of the gate trench using an atomic layer deposition (ALD) technique or a chemical vapor deposition (CVD) technique, or a combination thereof, by
exposing the interior surface of the gate trench to a pulse of a first precursor in a reaction chamber,
purging the reaction chamber with an inert gas,
exposing the interior surface of the gate trench to a pulse of a second precursor in the reaction chamber, and
purging the reaction chamber with an inert gas,
the first gate material comprising a transition metal alloyed with carbon, aluminum or nitrogen, or combinations thereof, to form a carbide, a nitride, or a carbo-nitride, or combinations thereof, of the transition metal; and
repeating a predetermined number of times the exposure of the interior surface of the gate trench to the pulse of the first precursor, the purging of the reaction chamber, the exposure of the interior surface of the gate trench to the pulse of the second precursor and purging the reaction chamber to achieve a predetermined thickness of the first gate material.

19. The method according to claim 18, wherein the first gate material formed on the interior surface of the gate trench comprises a work-function metal that sets a threshold voltage of the CMOS device at a predetermined threshold, the first gate material comprising an interior surface that corresponds to the interior surface of the gate trench,
the method further comprising:
forming a second gate material on the interior surface of the first gate material using an atomic layer deposition (ALD) technique or a chemical vapor deposition (CVD) technique, or a combination thereof, by
exposing the interior surface of the gate trench to a pulse of a first precursor in a reaction chamber;
purging the reaction chamber with an inert gas;
exposing the interior surface of the gate trench to a pulse of a second precursor in the reaction chamber;
purging the reaction chamber with an inert gas,
the second gate material comprising a transition metal alloyed with carbon, aluminum or nitrogen, or combinations thereof, to form a carbide, a nitride, or a carbo-nitride, or combinations thereof, of the transition metal; and
repeating a predetermined number of times the exposure of the interior surface of the first gate material to the pulse of the first precursor, the purging of the reaction chamber, the exposure of the interior surface of the first gate material to the pulse of the second precursor and purging the reaction chamber to achieve a predetermined thickness of the second gate material.

20. The method according to claim 19, further comprising wherein the second gate material formed on the interior surface of the first gate material comprises an adhesive layer or a barrier layer, or a combination thereof, the second gate material comprising an interior surface that corresponds to the interior surface of the first gate material and the gate trench,
the method further comprising:
forming a third gate material on the interior surface of the second gate material using an atomic layer deposition (ALD) technique or a chemical vapor deposition (CVD) technique, or a combination thereof, by
exposing the interior surface of the second gate material to a pulse of a first precursor in a reaction chamber,
purging the reaction chamber with an inert gas,
exposing the interior surface of the second gate material to a pulse of a second precursor in the reaction chamber, and
purging the reaction chamber with an inert gas,
the third gate material comprising a transition metal alloyed with carbon, aluminum or nitrogen, or combinations thereof, to form a carbide, a nitride, or a carbo-nitride, or combinations thereof, of the transition metal; and
repeating a predetermined number of times the exposure of the interior surface of the second gate material to the pulse of the first precursor, the purging of the reaction chamber, the exposure of the interior surface of the second gate material to the pulse of the second precursor and purging the reaction chamber to achieve a predetermined thickness of the third gate material.
